(19) United States
(12) Patent Application Publication
(10) Pub. No.: US 2014/0209285 A1
(43) Pub. Date: Jul. 31, 2014

(54) METHOD FOR MANUFACTURING COOLING DEVICE, COOLING DEVICE AND ELECTRONIC COMPONENT PACKAGE EQUIPPED WITH COOLING DEVICE

(71) Applicant: FUJITSU LIMITED, Kawasaki-shi (JP)

(72) Inventors: Yuki HOSHINO, Kawasaki (JP); KENJI FUKUZONO, Kawasaki (JP)

(73) Assignee: FUJITSU LIMITED, Kawasaki-shi (JP)

(21) Appl. No.: 14/064,239

(22) Filed: Oct. 28, 2013

(30) Foreign Application Priority Data
Jan. 28, 2013 (JP) 2013-013678

(51) Int. Cl. H05K 7/20; H05K 13/00

(52) U.S. Cl. CPC H05K 7/20218; H05K 13/00
USPC 165/166; 228/193; 419/5

(57) ABSTRACT

A method for manufacturing an integral molded cooling device, a circulation channel of a refrigerant being formed in the inside of the cooling device, the method includes: laminating a channel forming plate, a top plate and a bottom plate, a plurality of comb tooth units being provided on the channel forming plate; and integrating the channel forming plate, the top plate and the bottom plate by diffusion joining.

### CROSS-REFERENCE TO RELATED APPLICATIONS

This application is based upon and claims the benefit of priority of the prior Japanese Patent Application No. 2013-013678 filed on Jan. 28, 2013, the entire contents of which are incorporated herein by reference.

### FIELD

A certain aspect of the embodiments is related to a method for manufacturing a cooling device, a cooling device, and an electronic component package equipped with a cooling device.

### BACKGROUND

In recent years, with the improvement in the speed of the arithmetic processing speed in an electronic device, and the increase in a storage capacity, the calorific value of electronic components, such as a LSI (Large Scale Integration), included in the electronic device increases. The cooling device which cools the electronic components is proposed variously. For example, Japanese Laid-open Patent Publication No. 2001-53206 discloses a cooling device which has a cooling channel plate that performs heat exchange with cooling fluid as a refrigerant, and a cooling channel cover that covers the cooling channel plate. In the cooling device, a plurality of parallel cooling grooves through which the cooling fluid flows are formed on the cooling channel plate. The cooling channel plate has a through groove which crosses and pierces a part of the cooling channel plate corresponding to a position between adjoining semiconductor devices arranged in a direction in which the cooling grooves are formed. A turbulence promoter is arranged on the through groove. Thus, in the cooling device disclosed in Japanese Laid-open Patent Publication No. 2001-53206, the mounting of a sealing component (O-type ring) and a bolt fastening measure are employed in order to improve the reliability of airtight sealing between the cooling channel plate and the cooling channel cover.

### SUMMARY

According to an aspect of the present invention, there is provided a method for manufacturing an integral molded cooling device, a circulation channel of a refrigerant being formed in the inside of the cooling device, the method including: laminating a channel forming plate, a top plate and a bottom plate, a plurality of comb tooth units being provided on the channel forming plate; and

integrating the channel forming plate, the top plate and the bottom plate by diffusion joining.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a perspective view of a cooling device according to a first embodiment, as viewed from a top plate;

FIG. 1B is a perspective view of the cooling device according to the first embodiment, as viewed from a bottom plate;

FIG. 2 is a cross-section diagram, taken on a line A-A in FIG. 1, of an electronic component package equipped with the cooling device according to the first embodiment;

FIG. 3 is a flowchart of an example of a method for manufacturing the cooling device according to the first embodiment;

FIG. 4 is an explanatory diagram illustrating a state of the cooling device before diffusion joining according to the first embodiment;

FIGS. 5A to 5C are explanatory diagrams illustrating a channel forming plate used for the cooling device according to the first embodiment;

FIG. 6 is an explanatory diagram illustrating a relationship between a width and a thickness of grooves formed on the channel forming plate;

FIG. 7 is an explanatory diagram illustrating schematically a state of the diffusion joining;

FIGS. 8A to 8C are explanatory diagrams illustrating schematically the change of metal structure by the diffusion joining;

FIG. 9 is an explanatory diagram illustrating schematically a state of circulation of a refrigerant in the cooling device;

FIG. 10 is a perspective view of the cooling device according to a second embodiment;

FIG. 11 is a cross-section diagram taken on a line B-B in FIG. 10;

FIG. 12 is a cross-section diagram of the electronic component package according to a third embodiment;

FIG. 13 is a flowchart of an example of a method for manufacturing the cooling device according to the third embodiment;

FIG. 14 is an explanatory diagram illustrating a method for manufacturing the cooling device by metallurgy processing; and

FIG. 15 is an explanatory diagram illustrating schematically a state where a main material with which a sub-material has been coated changes to an alloy.

### DESCRIPTION OF EMBODIMENTS

As mentioned previously, the cooling device disclosed in Japanese Laid-open Patent Publication No. 2001-53206 is required to assemble a plurality of components. Therefore, a manufacturing cost may increase. When the cooling device is made into the structure which has assembled the plurality of components, a domain for fastening or joining each component must be secured, and the intensity of the structure must be secured at the same time. Therefore, a size of the cooling device becomes large. The problems of such intensity securement and size expansion affect the whole structure and each component of the cooling device. Expansion of the size of the component leads also to the weight trend of the component, and the weight of the cooling device increases. Therefore, it is considered that the burden of a substrate and a BGA (Ball Grid Array) which support the weight of the cooling device becomes large.

In addition, the size expansion of the component may also affect the cooling efficiency of the cooling device. That is, when the board thickness of the component which forms a refrigerant channel increases in order to secure the intensity of the component, the electronic component generating heat and the refrigerant are separated from each other, and cooling efficiency may reduce.

A description will now be given of embodiment of the present invention with reference to attached drawings. It should be noted that a size and ratio of each element do not correspond to the actual ones in some drawings. Also, some elements which exist in fact may be omitted in some drawings for convenience of explanation.

### First Embodiment

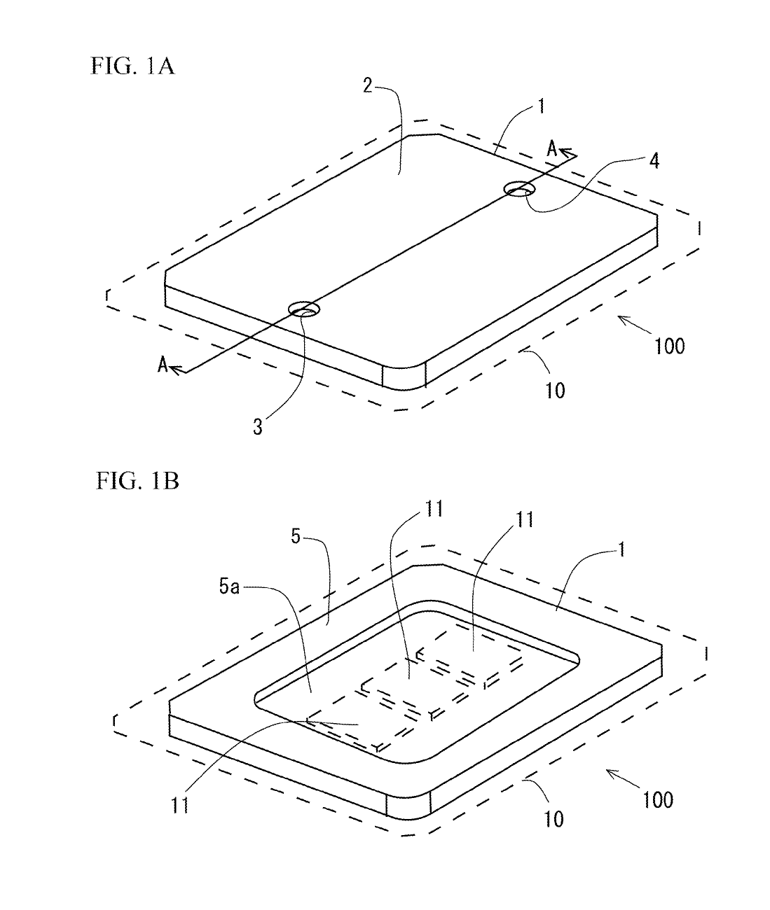

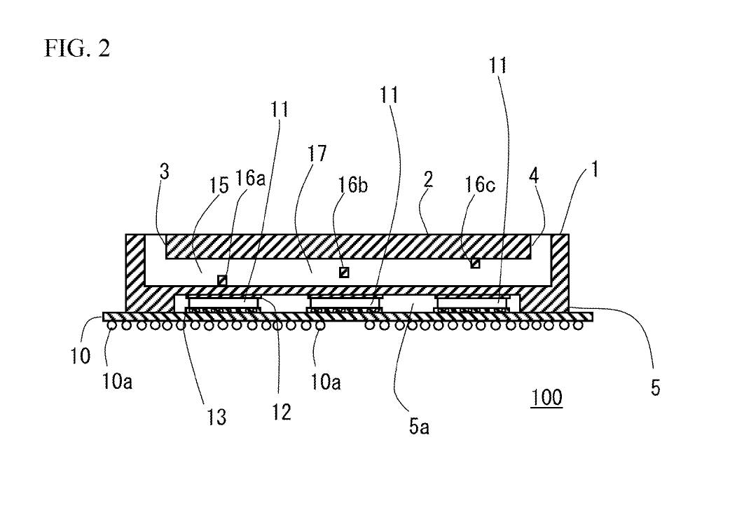

FIG. 1A is a perspective view of a cooling device 1 according to a first embodiment, as viewed from a top plate 2. FIG. 1B is a perspective view of the cooling device 1 according to the first embodiment, as viewed from a bottom plate 5. FIG. 2 is a cross-section diagram, taken on a line A-A in FIG. 1, of an electronic component package 100 equipped with the cooling device 1 according to the first embodiment.

Referring to FIGS. 1A and 1B, a substrate 10 is illustrated by a chain line.

The cooling device 1 is attached to the substrate 10 and forms the electronic component package 100. A conventional known junction method can be conventionally employed as junction of the cooling device 1 and the substrate 10. BGAs (Ball Grid Array) 10a are formed on the substrate 10, and LSIs (Large Scale Integration) 11 which are an example of electronic components are mounted on the substrate 10 through underfills 13. The cooling device 1 includes the top plate 2 and the bottom plate 5. The top plate 2 includes a refrigerant introduction port 3 and a refrigerant exhaust port 4. The bottom plate 5 includes a recessed portion 5a. The LSIs 11 are stored into the recessed portion 5a. Each of the LSIs 11 contacts the bottom plate 5 via TIMs (Thermal Interface Material) 12. That is, the cooling device 1 has a shape of a lid which covers the LSIs 11. A circulation channel 15 for the refrigerant divided with a plurality of fins 17 is formed in the inside of the cooling device 1. The cooling device 1 includes connection units 16a, 16b and 16c which connect the plurality of fins 17 and extend in a circulation direction of the refrigerant, i.e., a direction crossing a direction which proceeds to the refrigerant exhaust port 4 from the refrigerant introduction port 3. The cooling device 1 can also cool another electronic component other than the LSIs 11. Each of the fins 17 corresponds to a comb-plate unit, and the fins 17 are formed by laminating and integrating comb tooth units 6d, 7d and 8d as described later.

The cooling device 1 has an integration structure by the same material. Specifically, the cooling device 1 is integrally formed with copper material with good thermal conductivity. Here, the integration structure means an integrated structure without having a joint and a junction. That is, the cooling device 1 is the structure formed with a material which is combined atomically and becomes a lump on the metallographic structure level. Here, the copper material is an example, and another material may be used.

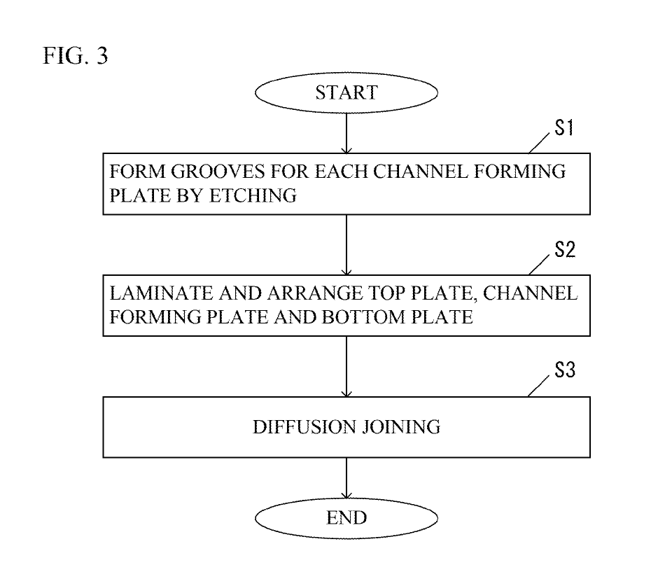

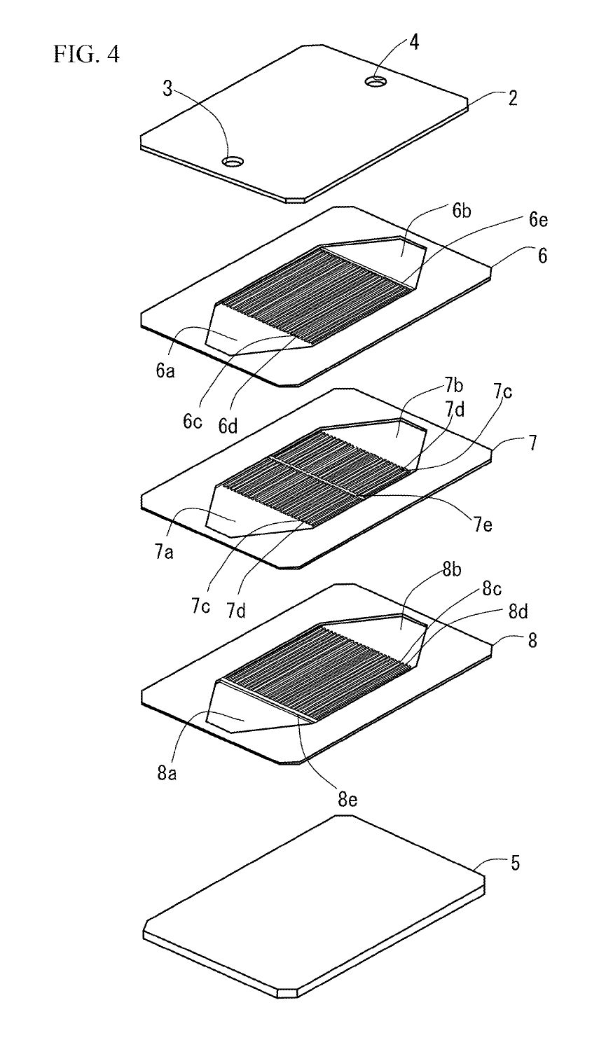

A description will be given of a method for manufacturing the cooling device 1, with reference to FIGS. 3 and 4. First, in step S1, grooves are formed on each of channel forming plates 6 to 8 by etching.

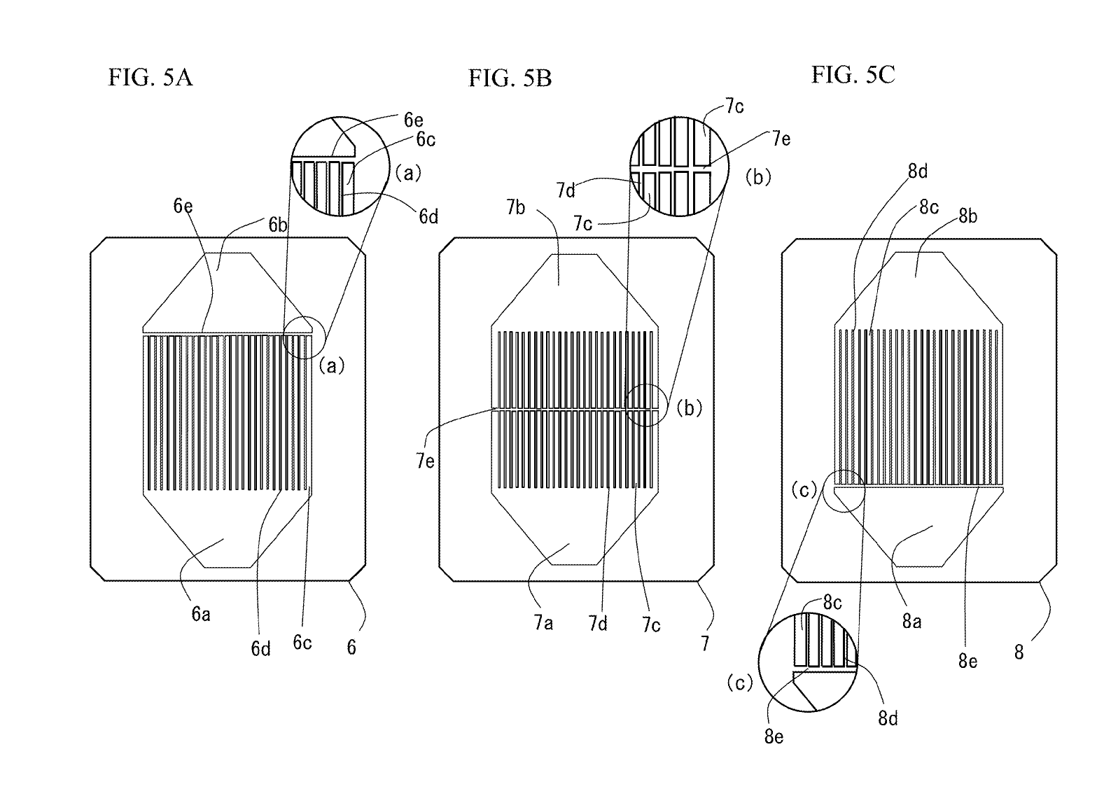

Referring to FIGS. 4 and 5, the channel forming plate 6 includes spaces 6a and 6b, a plurality of grooves 6c, and the plurality of comb tooth units 6d. The space 6a serves as a space in which the refrigerant introduction port 3 opens at the time of completion of the cooling device 1. The space 6b serves as a space in which the refrigerant exhaust port 4 opens at the time of completion of the cooling device 1. Each of the grooves 6c extends in a circulation direction of the refrigerant, i.e., the direction which proceeds to the refrigerant exhaust port 4 from the refrigerant introduction port 3. Each of the grooves 6c forms the circulation channel 15 for the refrigerant at the time of completion of the cooling device 1. The comb tooth units 6d have fin shapes, respectively, and extend along the circulation direction of the refrigerant as with the grooves 6c. The channel forming plate 6 has a connection unit 6e which extends in a direction crossing the comb tooth units 6d and the grooves 6c arranged in parallel, and connects the comb tooth units 6d. The connection unit 6e becomes the connection unit 16a at the time of completion of the cooling device 1. The spaces 6a and 6b, the grooves 6c, the comb tooth units 6d and the connection unit 6e are formed by etching. Thereby, the comb tooth units 6d and the connection unit 6e on the channel forming plate 6 become the same thickness. Here, the spaces 6a and 6b may be formed by lathe processing separately.

The channel forming plate 7 includes spaces 7a and 7b, a plurality of grooves 7c, and the plurality of comb tooth units 7d, as with the channel forming plate 6. The space 7a serves as a space in which the refrigerant introduction port 3 opens at the time of completion of the cooling device 1. The space 7b serves as a space in which the refrigerant exhaust port 4 opens at the time of completion of the cooling device 1. Each of the grooves 7c extends in a circulation direction of the refrigerant, i.e., the direction which proceeds to the refrigerant exhaust port 4 from the refrigerant introduction port 3. Each of the grooves 7c forms the circulation channel 15 for the refrigerant at the time of completion of the cooling device 1. The comb tooth units 7d have fin shapes, respectively, and extend along the circulation direction of the refrigerant as with the grooves 7c. The channel forming plate 7 has a connection unit 7e which extends in a direction crossing the comb tooth units 7d and the grooves 7c arranged in parallel, and connects the comb tooth units 7d. The connection unit 7e becomes the connection unit 16b at the time of completion of the cooling device 1. The spaces 7a and 7b, the grooves 7c, the comb tooth units 7d and the connection unit 7e are formed by etching. Thereby, the comb tooth units 7d and the connection unit 7e on the channel forming plate 7 become the same thickness. Here, the spaces 7a and 7b may be formed by lathe processing separately.

The channel forming plate 8 includes spaces 8a and 8b, a plurality of grooves 8c, and the plurality of comb tooth units 8d, as with the channel forming plate 6. The space 8a serves as a space in which the refrigerant introduction port 3 opens at the time of completion of the cooling device 1. The space 8b serves as a space in which the refrigerant exhaust port 4 opens at the time of completion of the cooling device 1. Each of the grooves 8c extends in a circulation direction of the refrigerant, i.e., the direction which proceeds to the refrigerant exhaust port 4 from the refrigerant introduction port 3. Each of the grooves 8c forms the circulation channel 15 for the refrigerant at the time of completion of the cooling device 1. The comb tooth units 8d have fin shapes, respectively, and extend along the circulation direction of the refrigerant as with the grooves 8c. The channel forming plate 8 has a connection unit 8e which extends in a direction crossing the comb tooth units 8d and the grooves 8c arranged in parallel, and connects the comb tooth units 8d. The connection unit 8e becomes the connection unit 16b at the time of completion of the cooling device 1. The spaces 8a and 8b, the grooves 8c, the comb tooth units 8d and the connection unit 8e are formed by etching. Thereby, the comb tooth units 8d and the connection unit 8e on the channel forming plate 8 become the same thickness. Here, the spaces 8a and 8b may be formed by lathe processing separately.

Thus, the channel forming plates 6, 7 and 8 include the connection units 6e, 7e and 8e, respectively. However, the formation positions of the connection units 6e, 7e and 8e are different from each other along the circulation direction of the refrigerant. That is, the connection unit 6e which the channel forming plate 6 includes is located in an upstream side of the circulation direction of the refrigerant. Therefore, the comb tooth units 6d have free ends at a downstream side of the circulation direction. The connection unit 7e which the channel forming plate 7 includes is located near the midstream of the circulation direction of the refrigerant. Therefore, the comb tooth units 7d have free ends at the upstream side and the downstream side of the circulation direction. The connection unit 8e which the channel forming plate 8 includes is located in a downstream side of the circulation direction of the refrigerant. Therefore, the comb tooth units 8d have free ends at the upstream side of the circulation direction. Thus, in a process to laminate the respective plates, the channel forming plates 6, 7 and 8 in which the formation positions of the connection units 6e, 7e and 8e are different from each other along the circulation direction of the refrigerant are arranged between the top plate 2 and the bottom plate 5. As a result, the positions of the connection units 16a, 16b, and 16c are mutually shifted. When the channel forming plates 6, 7 and 8 are laminated, the circulation channel of the refrigerant is secured. As described above, the connection units 6e, 7e and 8e become the connection unit 16a, 16b and 16c at the time of completion of the cooling device 1. Therefore, the connection units 6e, 7e, and 8e are installed in consideration of a circulation state of the refrigerant.

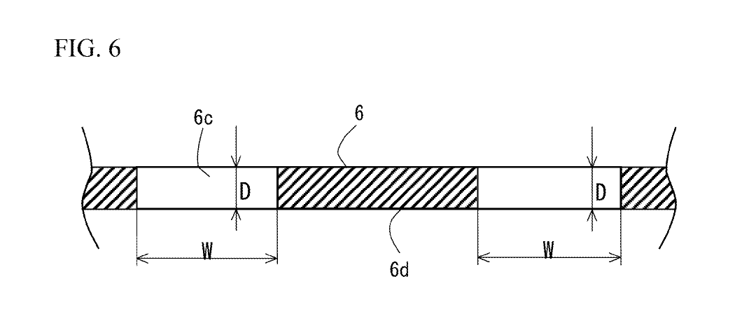

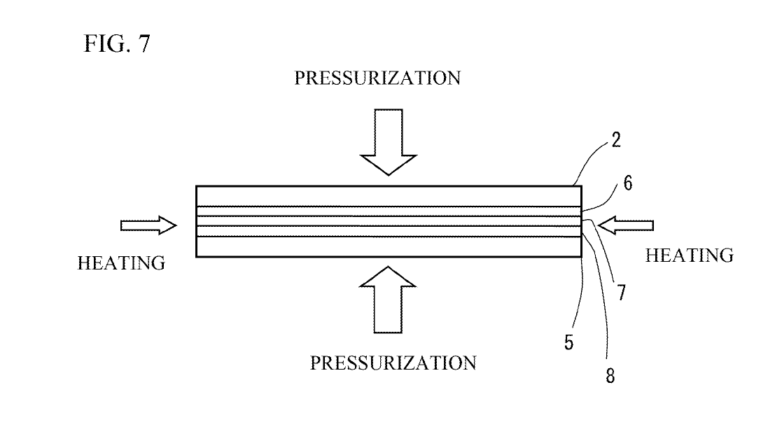

Next, in step S2, the top plate 2, the bottom plate 5, and the channel forming plates 6, 7 and 8 are laminated and arranged, as illustrated in FIG. 4. Thus, cooling efficiency can be improved by carrying out the lamination arrangement of the channel forming plates 6, 7 and 8. In order to improve the cooling efficiency, it is desirable that the area of a wall arranged in the circulation channel 15, i.e., the total surface area of the fins 17 which are comb-plate units becomes large. Here, the fins 17 are formed by laminating and integrating the comb tooth units 6d, 7d and 8d which the channel forming plates 6, 7 and 8 include, respectively. In order to expand the total surface area of the fins 17, it is desirable to increase the number of grooves as much as possible and to increase the number of comb tooth units in each of the channel forming plates 6, 7 and 8. In order to increase the number of grooves and the number of comb tooth units, it is necessary to narrow the width of each of the grooves, but the width of the groove receives the restriction of processing conditions. A description will be given of an example of the processing conditions, with reference to FIG. 6. FIG. 6 illustrates a width W and a depth D of the grooves 6c formed on the channel forming plate 6. When the grooves 6c are formed by etching, the width W and the depth D receive the restriction of an aspect ratio. That is, when the width W is narrowed, the depth D also becomes shallow. Therefore, when the width W is narrowed too much, each of the grooves 6c cannot penetrate the channel forming plate 6. When the thickness of the plate to be penetrated is made thin, the grooves with a narrow width can be formed. On the other hand, the total surface area of the fins 17 can be enlarged by laminating the channel forming plates. Here, in the preset embodiment, three channel forming plates 6, 7 and 8 are prepared. Although at least one or more channel forming plate needs to be prepared, the total surface area of the fins 17 can be enlarged by laminating the channel forming plates, as described above. When the number of channel forming plates is one, the comb tooth units become the comb-plate units, i.e., the fins.

Referring to FIG. 4, the refrigerant introduction port 3 and the refrigerant exhaust port 4 are formed on the top plate 2 before step S2 is performed. The refrigerant introduction port 3 and the refrigerant exhaust port 4 may be formed in a subsequent process, e.g. after step S3.

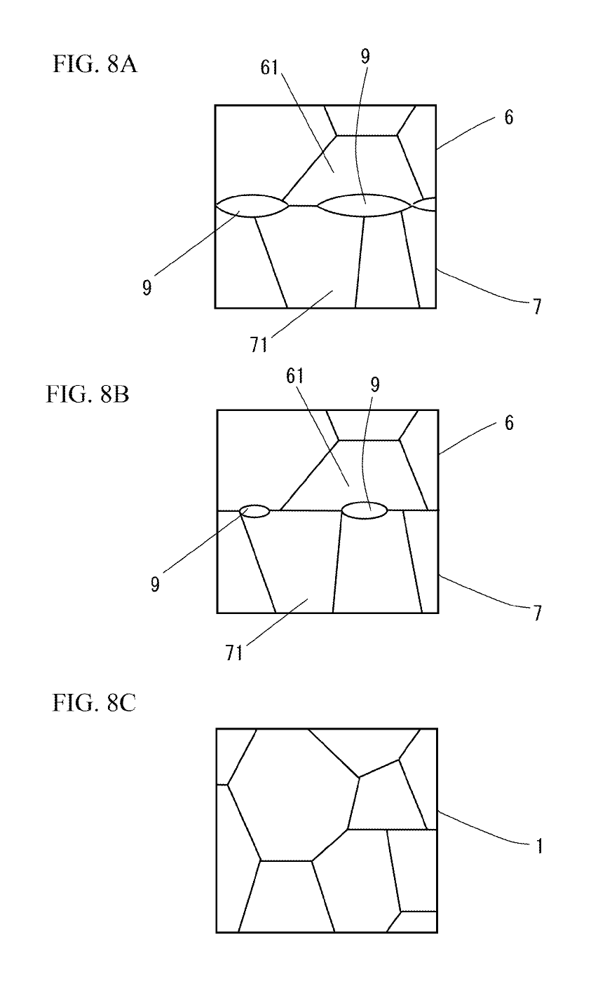

The diffusion joining is performed in step S3 performed subsequent to step S2. That is, the top plate 2, the bottom plate 5, and the channel forming plates 6, 7 and 8 which are laminated and arranged are pressurized vertically while being heated under an inert gas environment or a vacuum environment. FIGS. 8A to 8C illustrate states where the channel forming plates 6 and 7 are joined. Initially, gaps 9 exist between the channel forming plates 6 and 7, as illustrated in FIG. 8A. By pressurizing and heating the channel forming plates 6 and 7, the gaps 9 are reduced gradually, as illustrated in FIG. 8B. Finally, a metallographic structure 61 of the channel forming plate 6 and a metallographic structure 71 of the channel forming plate 7 are fused and integrated, as illustrated in FIG. 8C. Such a phenomenon occurs between the respective plates. As a result, the cooling device 1 in which all the laminated plates are integrated in a metallographic structure level to become the integration structure is formed.

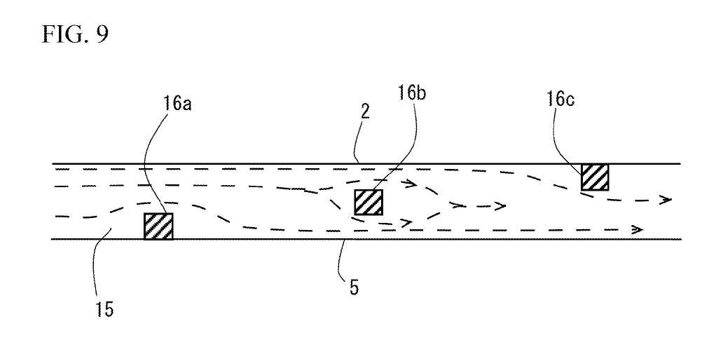

FIG. 9 illustrates schematically a state of circulation of the refrigerant in the cooling device 1. The refrigerant collides with the connection units 16a, 16b, and 16c, so that the flow of the refrigerant which flows through the inside of the circulation channel 15 is controlled. As a result, the refrigerant is agitated, and the refrigerant flows in an up-and-down direction of a cooling passage and between a top plate side and a bottom plate side. Therefore, heat exchange efficiency, i.e., cooling efficiency improves.

Unlike a case where a cooling device is assembled by welding, for example, the cooling device 1 does not have a junction. Therefore, it is not considered that stress is added to the junction, and the cooling device 1 is released from the worry about the composition change which arises in a welding part. Since the grooves are formed on the channel forming plates and the channel forming plates with the grooves are laminated, various channel shapes can be formed by performing detailed groove processing on each channel forming plate for each channel forming plate.

Since the cooling device 1 is an integral-molded article, the number of parts is reduced. Therefore, the cooling device 1 is released from the request of size expansion of the components when the structure which assembles the components is employed. As a result, the cooling device 1 has a compact structure. Although the cooling device 1 is small capacity, it secures required intensity. In addition, the cooling device 1 enables high-density implementation when the cooling device 1 is implemented on the electronic device. Since the cooling device 1 has a compact structure, the weight of the cooling device 1 is also reduced according to the reduction of the capacity of the components. By reducing the weight of the cooling device 1, the burden on BGA10a is reduced, and the curvature of the substrate 10 is restrained effectively. As a result, the reliability of the electronic component package 100 and an electronic device improves.

In addition, since a margin can be given to intensity with miniaturization, the thickness of each component can be set thinly. As a result, the refrigerant and the LSIs 11 can be approached, a heat thermal resistance can be reduced, and cooling efficiency can be improved. Since the cooling device 1 becomes compact, the space in the housing of the electronic device can be expanded, and the flow of the air in the housing becomes good. As a result, a cooling effect of another air-cooling components mounted on the electronic device improves.

Since the cooling device 1 is the integration structure and has no joint, it is released from a possibility that a liquid leak arises. Thereby, in a product testing, an airtight testing can also be excluded. As a result, the process of a reliability test can be shortened. Since a sealing member becomes unnecessary, there are also no worries about degradation of the sealing member. It is possible to operate apparatus under high reliability in the maintenance-free state over a long period of time, as compared with the conventional device.

### Second Embodiment

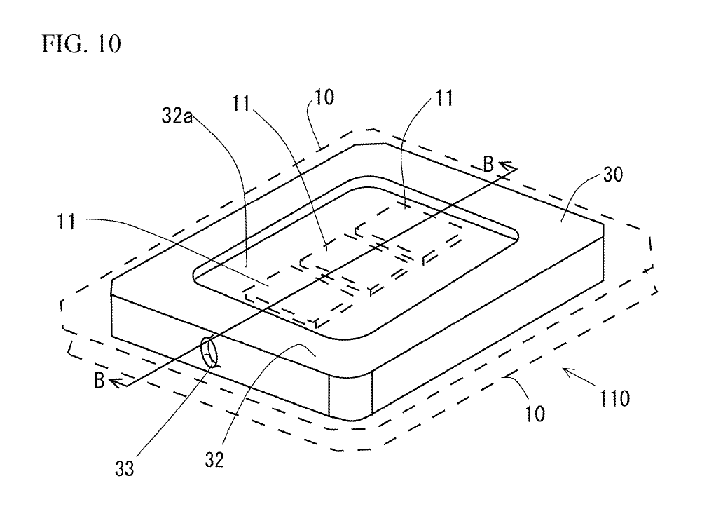

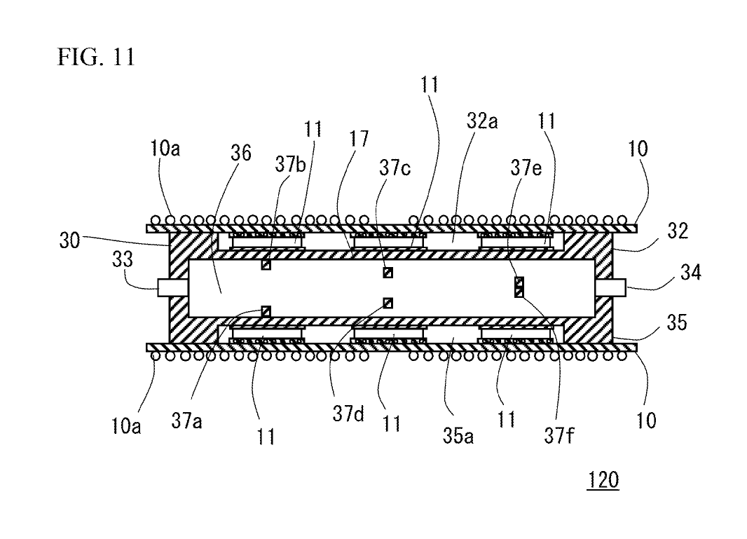

Next, a description will be given of a second embodiment, with reference to FIGS. 10 and 11. FIG. 10 is a perspective view of a cooling device 30 according to the second embodiment. FIG. 11 is a cross-section diagram taken on a line B-B in FIG. 10. The cooling device 30 differs from the cooling device 1 of the first embodiment in that the cooling device 30 includes recessed portions 32a and 35a near the top plate 32 and the bottom plate 35, respectively. The LSIs 11 mounted on the substrate 10 are stored into each of the recessed portions 32a and 35a. Thereby, the cooling device 30 can form an electronic component package 110 which includes the substrates 10 on a plurality of surfaces. A conventional known junction method can be conventionally employed as junction of the cooling device 30 and the substrates 10. The cooling device 30 includes a circulation channel 36 of the refrigerant, and connection units 37a to 37f.

As with the first embodiment, the cooling device 30 is formed by arranging the channel forming plates between the top plate 32 and the bottom plate 35, and performing the diffusion joining Therefore, as with the cooling device 1 of the first embodiment, the cooling device 30 has the integration structure integrated in a metallographic structure level. Thereby, the cooling device 30 of the second embodiment can obtain the same effect as the cooling device 1 of the first embodiment. Unlike the first embodiment, the cooling device 30 includes a refrigerant introduction port 33 and a refrigerant exhaust port 34 on the side surfaces of the cooling device 30. The refrigerant introduction port 33 and the refrigerant exhaust port 34 are formed by drilling after the diffusion joining

### Third Embodiment

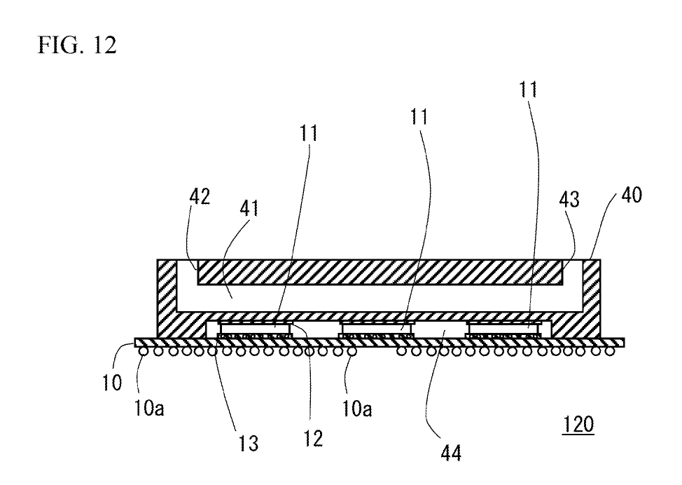

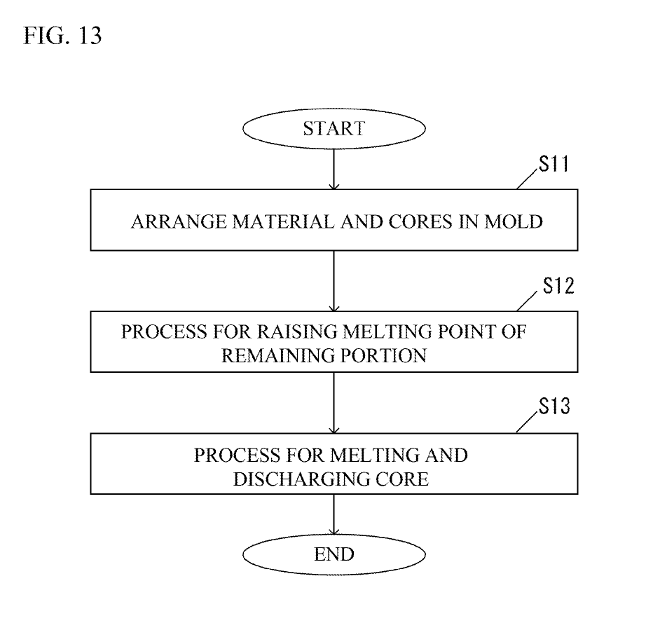

Next, a description will be given of a third embodiment, with reference to FIGS. 12 to 15. Referring to FIG. 12, a cooling device 40 includes a refrigerant introduction port 42, a refrigerant exhaust port 43, and a circulation channel 41 of the refrigerant, as with the cooling device 1 of the first embodiment. A recessed portion 44 storing the LSIs 11 mounted on the substrate 10 is provided. The cooling device 40 forms an electronic component package 120 by being mounted on the substrate 10, as with the first embodiment. Here, the cooling device 40 differs from the cooling device 1 of the first embodiment in that the cooling device 40 includes no connection unit. The cooling device 40 including no connection unit can be manufactured by the following method. Hereinafter, the manufacturing method is explained according to a flowchart illustrated in FIG. 13.

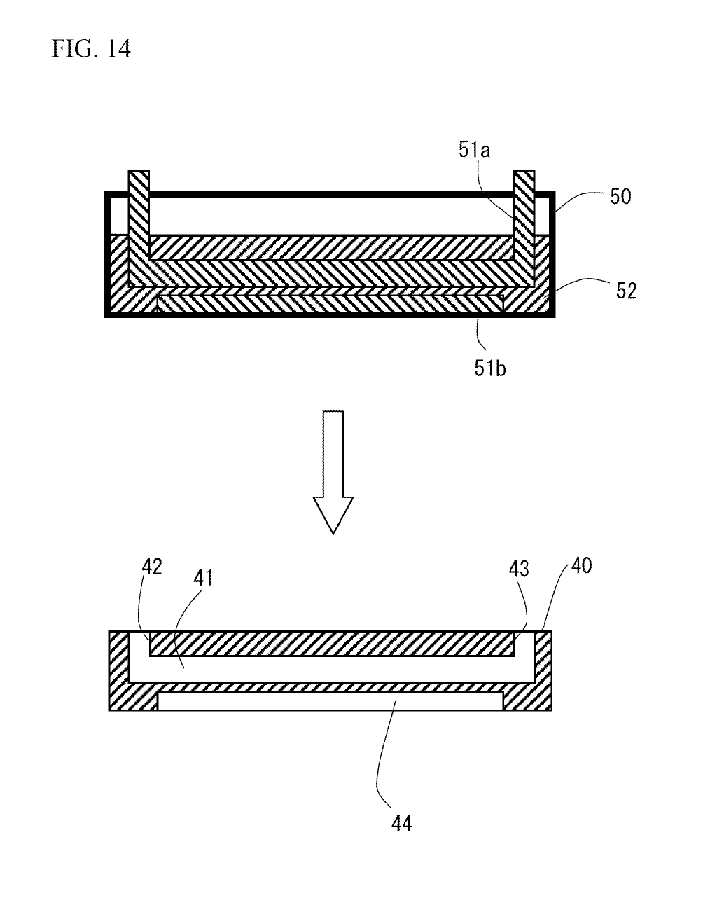

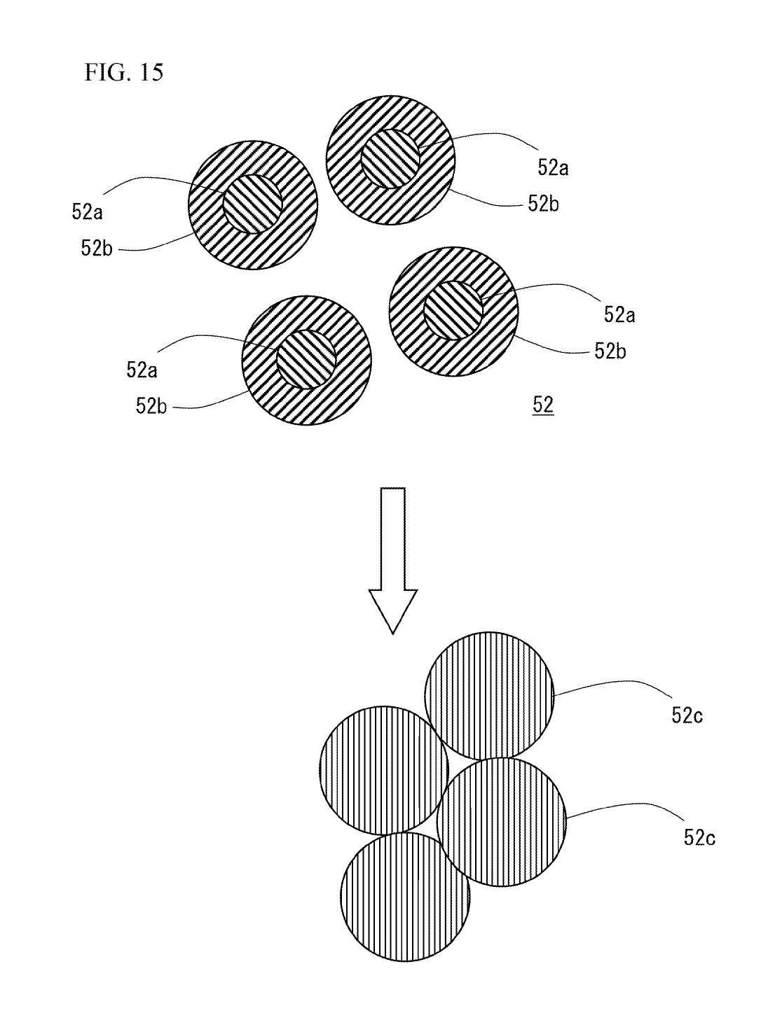

First, in step S11, a material 52, and cores 51a and 51b are arranged in a mold 50, as illustrated in FIG. 14. The core 51a forms the circulation channel 41. The core 51b forms the recessed portion 44. The material 52 is a powder material in which the circumference of a base material 52a is coated with a sub-material 52b, as illustrated in FIG. 15. By heating, the material 52 becomes an alloy 52c of the base material 52a and the sub-material 52b, and can be sintered. Here, it is assumed that a sintering temperature is T1, a melting temperature of the cores 51a and 51b is T2, and a melting point of the alloy 52c is T4. In such temperatures, the relation of “T1<T2<T4” is satisfied.

In step S12, in order to change the material 52 which forms a remaining portion, i.e., the outer shape of the cooling device 40 to the alloy 52c, the measure for raising the melting point of the material 52 is performed. Concretely, the temperature of the material 52 is raised to T1. Thereby, the base material 52a and the sub-material 52b are changed to the alloy 52c whose melting point is T4.

In step S13, the cores 51a and 51b are melted and discharged. Specifically, a temperature T3 which satisfies the conditions of “T2<T3<T4” is set. Thereby, the alloy 52c maintains the shape thereof without melting, and only the cores 51a and 51b melt. If the melted cores 51a and 51b are discharged, the cooling device 40 which is the integration structure by the same material can be obtained.

In the first to the third embodiments described above, the circulation direction of the refrigerant is a single direction. However, the circulation channel of the refrigerant may be bent and the refrigerant may shuttle in the cooling device, for example. In addition, the circulation channel of the refrigerant may be divided into an outgoing channel and a return channel, and the circulation directions of the refrigerant which passes through the outgoing channel and the return channel may be opposed to each other. Moreover, a pillar-shaped unit may be provided on the circulation channel of the refrigerant. The pillar-shaped unit is provided on the circulation channel, so that the intensity of the cooling device can increase, and the cooling efficiency can be improved by controlling the flow of the refrigerant. The numbers of refrigerant introduction ports and refrigerant exhaust ports may be changed as appropriate. Moreover, the cooling device can also use a boiling phenomenon as a cooling system.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A method for manufacturing an integral molded cooling device, a circulation channel of a refrigerant being formed in the inside of the cooling device, the method comprising:
laminating a channel forming plate, a top plate and a bottom plate, a plurality of comb tooth units being provided on the channel forming plate; and
integrating the channel forming plate, the top plate and the bottom plate by diffusion joining.

2. The method for manufacturing the cooling device as claimed in claim 1, wherein the channel forming plate includes a connector that extends in a direction crossing the plurality of comb tooth units and connects the plurality of comb tooth units.

3. The method for manufacturing the cooling device as claimed in claim 2, wherein in the laminating, a plurality of channel forming plates are arranged between the top plate and the bottom plate, positions of connectors on the channel forming plates being different from each other along a circulation direction of the refrigerant.

4. The method for manufacturing the cooling device as claimed in claim 2, wherein the comb tooth units and the connector of the channel forming plate are the same thickness.

5. A method for manufacturing an integral molded cooling device, a circulation channel of a refrigerant being formed in the inside of the cooling device, the method comprising:
arranging, in a mold, a core for forming the circulation channel, and a powder material in which a main material is coated with a sub-material;
sintering the powder material and changing the main material and the sub-material to an alloy having a melting point higher than a melting point of the core by heating the powder material; and
melting and discharging the core.

6. A cooling device comprising:
a plurality of comb-plate units;
a circulation channel for a refrigerant divided with the comb-plate units; and
a connector that extends in a direction crossing a circulation direction of the refrigerant, and connects the comb-plate units;
wherein the cooling device has an integration structure by the same material.

7. An electronic component package comprising:
a cooling device; and
a substrate on which an electronic component and the cooling device are mounted;
the cooling device including:
a plurality of comb-plate units;
a circulation channel for a refrigerant divided with the comb-plate units; and
a connector that extends in a direction crossing a circulation direction of the refrigerant, and connects the comb-plate units;
wherein the cooling device has an integration structure by the same material.
